(19) United States
(12) Patent Application Publication
(10) Pub. No.: US 2010/0032410 A1
(43) Pub. Date: Feb. 11, 2010

(54) SUBSTRATE PROCESSING APPARATUS AND SUBSTRATE PROCESSING METHOD

(76) Inventors: Hiroshi Ootaguro, Kanazawa-shi (JP); Yasunori Kihara, Nomi-gun (JP); Yuji Ogino, Hakusan-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/535,228

(22) Filed: Aug. 4, 2009

(30) Foreign Application Priority Data
Aug. 5, 2008 (JP) 2008-201957

(51) Int. Cl. B44C 1/22; C23C 16/54; C23F 1/08; C23C 16/44; B05D 1/18; B08B 3/00

(52) U.S. Cl. 216/58; 118/715; 118/400; 156/345.11; 156/345.1; 427/248.1; 216/83; 427/430.1; 134/99.1

(57) ABSTRACT

A substrate processing apparatus includes a bath in which a liquid or a gas is fed, and a mechanism which feeds out a liquid or a gas into the bath. The substrate processing apparatus processes a to-be-processed substrate which is disposed in the bath. The mechanism includes a first feed-out device and a second feed-out device configured to feed out the liquid or gas into the bath, the first feed-in device configured to start/stop the feed-out of the liquid or gas from the first feed-out device, and second feed-in device configured to start/stop the feed-out of the liquid or gas from the second feed-out device.

### CROSS-REFERENCE TO RELATED APPLICATIONS

This application is based upon and claims the benefit of priority from prior Japanese Patent Application No. 2008-201957, filed Aug. 5, 2008, the entire contents of which are incorporated herein by reference.

### BACKGROUND OF THE INVENTION

1. Field of the Invention

The present invention relates to a substrate processing apparatus and a substrate processing method which performs cleaning, film formation, etching, etc. with a liquid or a gas, in a process of fabricating a planar substrate such as a liquid crystal display device, a semiconductor device, or a printed board.

2. Description of the Related Art

In recent years, with an increasing demand for reduction in size and weight of electronic equipment, there also is a demand for reduction in thickness of a substrate such as a printed board.

On the other hand, in the process of fabricating a planar substrate such as a liquid crystal display device, a semiconductor device or a printed board, to improve the in-plane uniformity of the process is always necessary in order to improve the product performance and manufacturing yield. For example, when chemical polishing is performed with use of a process bath, the in-plane uniformity is generally enhanced if the size of the process bath is sufficiently large, compared to the size of the substrate.

In the manufacture of the liquid crystal display device, in order to enhance the efficiency, large plates, from which plural substrates are to be cut out, are used as a pair of insulative substrates, and a plurality of display devices are formed between the paired insulative substrates. Subsequently, the thickness of the insulative substrate is reduced to a desired thickness by either mechanical polishing or chemical polishing, thereby to reduce the thickness and weight of the insulative substrate.

Conventionally, there has been proposed a method of manufacturing a liquid crystal display device which improves the manufacturing yield by fabricating a pair of substrates with different temperature histories, bonding these substrates together, and simultaneously reducing the thickness of these substrates by subjecting the major surfaces thereof to a chemical process (see Jpn. Pat. Appln. KOKAI Publication No. 2007-52367).

In recent years, with the increase in size of glass substrates, which are to-be-processed substrates, and in size of silicon wafers of semiconductor devices, if the size of the process bath is increased or if the substrates are moved in the process bath, the processing apparatus would become large in scale. Consequently, it becomes more difficult to decrease processing variances within substrate surfaces or among substrates.

In the case of performing etching, film formation or cleaning with use of a liquid or a gas (hereinafter referred to as “liquid or the like”), the process progresses to a greater degree on that part of the substrate, to which the liquid or the like is jetted, resulting in non-uniformity in in-plane thickness.

For example, in the step of subjecting the glass substrate to chemical polishing to reduce the thickness thereof, the glass substrate is put in a cassette, and immersed in a polishing liquid in the process bath. Then, air is fed out from tubes which are disposed on the bottom part of the process bath, and the polishing liquid is stirred. As described above, when the glass substrate is polished, that part of the glass substrate, to which the air from the tubes is applied, that is, that part of the glass substrate, which is positioned at the bottom part of the process bath, is reduced in thickness, leading to degradation in product performance. Besides, since the end portions of the glass substrate are not usable for product manufacturing, the manufacturing yield would deteriorate.

In particular, in the case where the thickness of the part where an integrated circuit is disposed is non-uniform, there would occur defective implementation of the integrated circuit disposed on the substrate, leading to a decrease in manufacturing yield. Furthermore, in the case where the thickness of a pair of substrates is non-uniform in the manufacturing process of the liquid crystal display device, alignment between parts would become difficult when a liquid crystal display panel is cut out of the paired substrates and the liquid crystal display panel is disposed, for example, in a frame.

### BRIEF SUMMARY OF THE INVENTION

According to a first aspect of the present invention, there is provided a substrate processing apparatus comprising a bath in which a liquid or a gas is fed, and a mechanism which feeds out a liquid or a gas into the bath, and processing a to-be-processed substrate which is disposed in the bath, the mechanism including first feed-out means and second feed-out means for feeding out the liquid or gas into the bath, first feed-in means for starting/stopping the feed-out of the liquid or gas from the first feed-out means, and second feed-in means for starting/stopping the feed-out of the liquid or gas from the second feed-out means.

According to a second aspect of the present invention, there is provided a substrate processing method comprising a step of disposing a to-be-processed substrate in a bath, a step of feeding out the liquid or gas into the bath form first feed-out means; and,

a step of feeding out the liquid or gas into the bath from second feed-out means, wherein the distribution of the jetted liquid or air is made spatially or temporally variable.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 schematically shows an example of the structure of a to-be-processed substrate which is processed by a substrate processing apparatus according to an embodiment of the present invention;

FIG. 2A is a view for describing a structure example of a substrate processing apparatus according to a first embodiment of the present invention;

FIG. 2B is a view for describing the structure example of the substrate processing apparatus according to the first embodiment of the present invention;

FIG. 2C is a view for describing the structure example of the substrate processing apparatus according to the first embodiment of the present invention;

FIG. 3A is a view for describing a structure example of a substrate processing apparatus according to a second embodiment of the present invention;

FIG. 3B is a view for describing the structure example of the substrate processing apparatus according to the second embodiment of the present invention;

FIG. 4A is a view for describing a structure example of a substrate processing apparatus according to a third embodiment of the present invention;

FIG. 4B is a view for describing the structure example of the substrate processing apparatus according to the third embodiment of the present invention;

FIG. 5A is a view for describing a structure example of a substrate processing apparatus according to a fourth embodiment of the present invention; and

FIG. 5B is a view for describing the structure example of the substrate processing apparatus according to the fourth embodiment of the present invention.

### DETAILED DESCRIPTION OF THE INVENTION

A substrate processing apparatus and substrate processing method according to a first embodiment of the present invention will now be described with reference to the accompanying drawings. The substrate processing apparatus according to this embodiment is a substrate processing apparatus which is used when a transparent insulative substrate of a liquid crystal display device, which is a to-be-processed body, is subjected to cleaning, film formation, or etching (polishing) with use of a liquid or a gas.

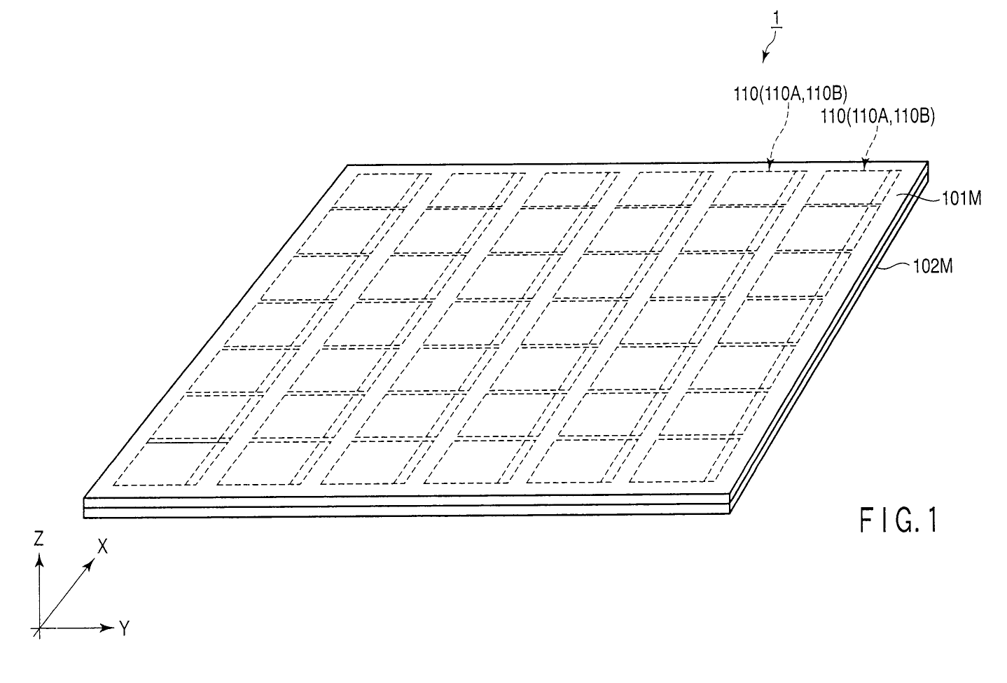

A to-be-processed substrate 1 of the substrate processing apparatus according to this embodiment includes a pair of substantially rectangular transparent insulative substrates which are disposed to be opposed to each other. As shown in FIG. 1, the paired substrates comprise a first substrate 101M and a second substrate 102M which is disposed to be opposed to the first substrate 101M. The first substrate 101M and second substrate 102M are transparent glass substrates.

The first substrate 101M includes a first display region 110A. The first display region 110A includes a plurality of pixel electrodes (not shown) which are arrayed in a matrix, and switching elements which are disposed near the associated pixel electrodes. The first substrate 101M further includes various wiring lines (not shown), such as driving wiring lines, which extend around the first display region 110A, thereby to drive the plural pixel electrodes. The second substrate 102M includes a second display region 110B which includes a counter-electrode that is opposed to the plural pixel electrodes.

The first substrate 101M and the second substrate 102M are aligned such that the first display region 110A and second display region 110B are opposed. In addition, the first substrate 101M and the second substrate 102M are fixed by a sealing member (not shown) which is disposed between the first substrate 101M and the second substrate 102M in a manner to surround the first display region 110A and second display region 110B. The sealing member includes a filling port for filling a liquid crystal material later.

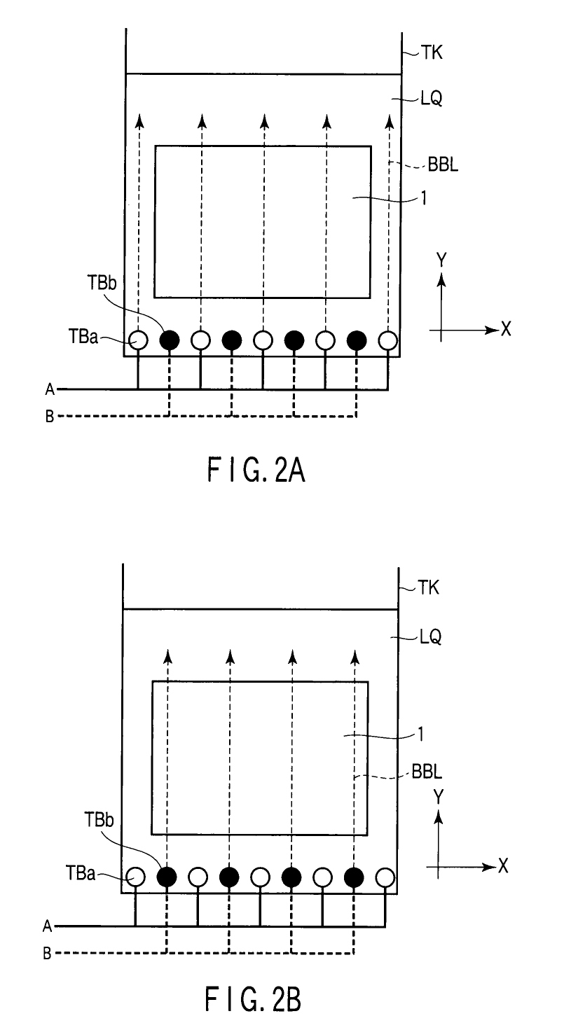

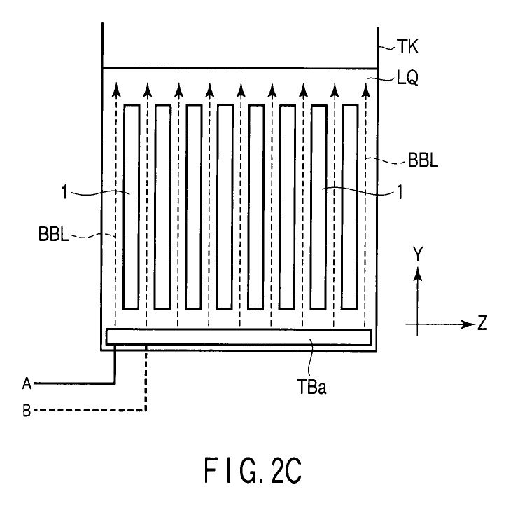

The substrate processing apparatus according to the present embodiment includes a process bath TK in which a liquid or a gas is put, and a feed-out mechanism which feeds out the liquid or gas into the process bath TK. In the substrate processing apparatus shown in FIG. 2A to FIG. 2C, the process bath TK is filled with a polishing liquid LQ for polishing, for example, a to-be-processed body.

In the substrate processing apparatus according to the embodiment, a solution containing hydrofluoric acid is used as the polishing liquid LQ. The level of the polishing liquid LQ may be lower than the upper end of the process bath TK. Alternatively, the polishing liquid LQ may be successively fed to overflow, and may be circulated via a circulation path which is provided outside the process bath TK.

When the to-be-processed substrates 1 are subjected to a polishing process as to-be-processed bodies, the to-be-processed substrates 1 are arranged in a cassette (not shown) or the like, as shown in FIG. 2A to FIG. 2C, and the to-be-processed substrates 1 in the cassette are immersed in the polishing liquid in the process bath TK. The to-be-processed substrates 1 are arranged such that their to-be-processed surfaces (substantially parallel to an XY plane) are substantially perpendicular to the bottom surface (substantially parallel to a ZX plane) of the process bath TK and that the to-be-processed surfaces are juxtaposed at intervals so as not to contact each other, by means of partitions provided on the cassette or the like.

The mechanism for feeding out the liquid or gas into the process bath TK includes a feed-out mechanism which feeds out the liquid or gas into the process bath TK, and a feed-in mechanism which starts/stops the feed-out of the liquid or gas from the feed-out mechanism.

The feed-out mechanism for feeding out the liquid or gas into the process bath TK is disposed near the bottom part of the process bath TK. As shown in FIG. 2A to FIG. 2C, in the substrate processing apparatus according to the embodiment, the feed-out mechanism includes a plurality of first tubes TBa and second tubes TBb extending in a direction (Z direction) substantially perpendicular to the to-be-processed surfaces of the to-be-processed substrates 1; an external feed-in mechanism A which feeds the liquid or gas from the outside of the process bath TK into the first tubes TBa; and an external feed-in mechanism B which feeds the liquid or gas from the outside of the process bath TK into the first tubes TBb.

As shown in FIG. 2A and FIG. 2B, the axial directions of the first tubes TBa and second tubes TBb are substantially parallel to the bottom surface (substantially parallel to the XZ plane), and the first tubes TBa and second tubes TBb are alternately arranged in a direction (X direction) substantially perpendicular to the X axis direction such that the axial directions of the first tubes TBa and second tubes TBb are substantially parallel to each other.

Each of the first tubes TBa and second tubes TBb has, for instance, a plurality of feed-out ports from which the liquid or gas is fed out. These feed-out ports are disposed, for example, at predetermined intervals in the axial direction (Z direction) of the first tubes TBa and second tubes TBb.

Instead of the above-described feed-out ports, each of the first tubes TBa and second tubes TBb may have, for instance, a linear feed-out port extending in parallel to the axial direction (Z direction) of the tube TB, or a plurality of feed-out ports which are disposed in a staggered fashion in the axial direction of the tube TB.

In the substrate processing apparatus according to the embodiment, as shown in FIG. 2A and FIG. 2B, air is fed in the first tubes TBa and second tubes TBb from the external feed-in mechanism A and external feed-in mechanism B, and the air is fed out into the process bath TK from the feed-out ports of the first tubes TBa and second tubes TBb. Thereby, the polishing liquid LQ in the process bath TK is stirred.

Specifically, in the substrate processing apparatus according to the embodiment, as shown in FIG. 2A, compressed air is first fed in the first tubes TBa from the external feed-in mechanism A. The air that is fed in the first tubes TBa is jetted from the feed-out ports that are formed in the surfaces of the first tubes TBa, and rises as bubbles BBL in the polishing liquid LQ.

Subsequently, as shown in FIG. 2B, compressed air is fed in the second tubes TBb which are connected to the external feed-in mechanism B. The compressed air that is fed in the second tubes TBb is jetted from the feed-out ports that are formed in the surfaces of the second tubes TBb, and rises as bubbles BBL in the polishing liquid LQ.

As has been described above, the distribution of the jetted liquid or air is made spatially or temporally variable. Thereby, the flow of the process liquid LQ in the process bath TK can be varied. Specifically, the first tubes TBa and second tubes TBb are alternately arranged in the X direction, and a first period in which the air is jetted from the first tubes TBa and a second period in which the air is jetted from the second tubes TBb are set. Thereby, the flow of the process liquid LQ in the process bath TK can be varied, and it becomes possible to obtain the same advantageous effect as the effect that is obtained by moving the to-be-processed substrates 1 in the process bath TK.

As has been described above, in the substrate processing apparatus according to the present embodiment, there is no need to move the to-be-processed substrates 1. Thus, without configuring the processing apparatus in a large scale, a greater number of to-be-processed substrates 1 can be processed, and the in-plane uniformity and the uniformity among substrates can be improved.

Therefore, the present embodiment can provide a substrate processing apparatus which can reduce a variance in thickness within a substrate surface or between substrates, and can improve product performance and manufacturing yield.

In the meantime, that the thickness of the to-be-processed substrate 1 becomes uniform means, for example, the case in which the difference in thickness (width in the Z direction) between a thickest part and a thinnest part of the to-be-processed substrate 1, or each of the first substrate 101M and second substrate 102M, becomes a predetermined value or less. In the substrate processing apparatus according to the present embodiment, the difference in thickness (width in the Z direction) between a thickest part and a thinnest part of the to-be-processed substrate 1 is about 1.5 μm or less.

Next, a substrate processing apparatus and substrate processing method according to a second embodiment of the present invention is described with reference to the accompanying drawings. In the description below, the structural parts common to those of the substrate processing apparatus according to the above-described first embodiment are denoted by like reference numerals, and a description thereof is omitted.

The substrate processing apparatus according to the present second embodiment, like the substrate processing apparatus according to the above-described first embodiment, is a substrate processing apparatus which is used when a transparent insulative substrate of a liquid crystal display device, which is a to-be-processed body, is subjected to cleaning, film formation, or etching (polishing) with use of a liquid or a gas.

In the substrate processing apparatus according to the present embodiment, the mechanism for feeding out the liquid or gas into the process bath TK includes a feed-out mechanism which feeds out the liquid or gas into the process bath TK, and a feed-in mechanism which starts/stops the feed-out of the liquid or gas from the feed-out mechanism.

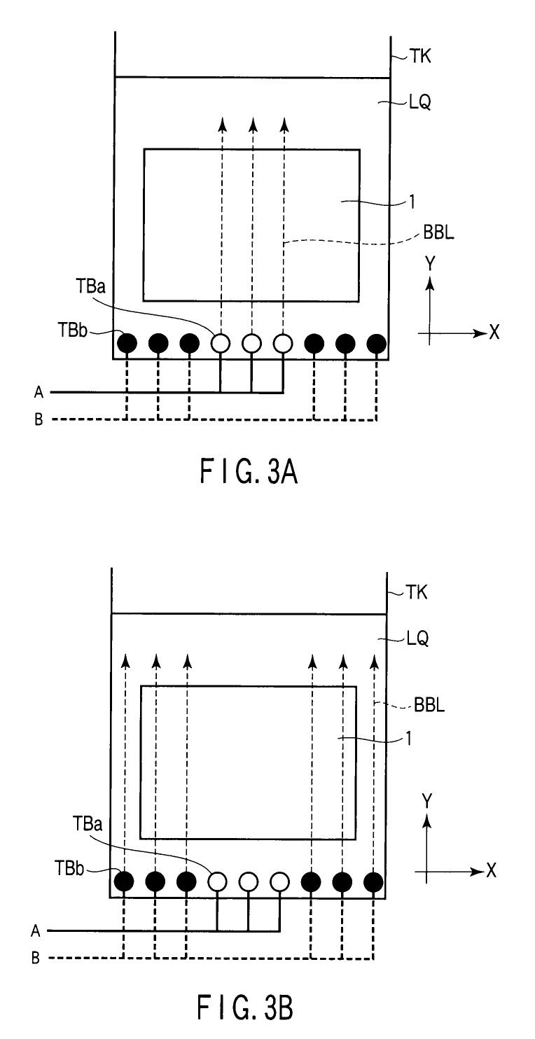

As shown in FIG. 3A and FIG. 3B, the feed-out mechanism is disposed near the bottom part of the process bath TK. In the substrate processing apparatus according to the embodiment, the feed-out mechanism includes a plurality of first tubes TBa and second tubes TBb extending in a direction (Z direction) substantially perpendicular to the to-be-processed surfaces of the to-be-processed substrates 1; an external feed-in mechanism A which feeds the liquid or gas from the outside of the process bath TK into the first tubes TBa; and an external feed-in mechanism B which feeds the liquid or gas from the outside of the process bath TK into the second tubes TBb.

The axial directions of the first tubes TBa and second tubes TBb are substantially parallel to the bottom surface (substantially parallel to the XZ plane), and the first tubes TBa and second tubes TBb are juxtaposed in a direction (X direction) substantially perpendicular to the X axis direction such that their axial directions are substantially parallel to each other.

The plural first tubes TBa are disposed at a central portion of the process bath TK in the X direction. The second tubes TBb are disposed at end portions of the process bath TK in the X direction. Each of the first tubes TBa and second tubes TBb has a plurality of feed-out ports from which the liquid or gas is fed out. These feed-out ports are disposed, for example, at predetermined intervals in the axial direction (Z direction) of the first tubes TBa and second tubes TBb.

In the substrate processing apparatus according to the embodiment, as shown in FIG. 3A and FIG. 3B, air is fed in the first tubes TBa and second tubes TBb from the external feed-in mechanism A and external feed-in mechanism B, and the air is fed out into the process bath TK from the feed-out ports of the first tubes TBa and second tubes TBb. Thereby, the polishing liquid LQ in the process bath TK is stirred.

Specifically, in the substrate processing apparatus according to the embodiment, as shown in FIG. 3A, compressed air is first fed in the first tubes TBa from the external feed-in mechanism A. The compressed air that is fed in the first tubes TBa is jetted from the feed-out ports that are formed in the surfaces of the first tubes TBa, and rises as bubbles BBL in the polishing liquid LQ.

Subsequently, as shown in FIG. 3B, compressed air is fed in the second tubes TBb from the external feed-in mechanism B. The compressed air that is fed in the second tubes TBb is jetted from the feed-out ports that are formed in the surfaces of the second tubes TBb, and rises as bubbles BBL in the polishing liquid LQ.

As has been described above, the distribution of the jetted liquid or air is made spatially or temporally variable. Thereby, the flow of the process liquid LQ in the process bath TK can be varied. In the X direction, the first tubes TBa are disposed at a central portion of the process bath TK, and the second tubes TBb are disposed at end portions of the process bath TK. In addition, the first period in which the air is jetted from the first tubes TBa and the second period in which the air is jetted from the second tubes TBb are alternately repeated. Thereby, the flow of the process liquid LQ in the process bath TK can be varied, and it becomes possible to obtain the same advantageous effect as the effect that is obtained by moving the to-be-processed substrates 1 in the process bath TK.

As has been described above, in the substrate processing apparatus according to the present embodiment, there is no need to move the to-be-processed substrates 1. Thus, without configuring the processing apparatus in a large scale, a greater number of to-be-processed substrates 1 can be processed, and the in-plane uniformity and the uniformity among substrates can be improved.

Therefore, the present embodiment can provide a substrate processing apparatus which can reduce a variance in thickness within a substrate surface or between substrates, and can improve product performance and manufacturing yield, like the substrate processing apparatus of the above-described first embodiment.

Next, a substrate processing apparatus and substrate processing method according to a third embodiment of the present invention is described with reference to the accompanying drawings. The substrate processing apparatus according to the present embodiment, like the substrate processing apparatus according to the above-described first embodiment, is a substrate processing apparatus which is used when a transparent insulative substrate of a liquid crystal display device, which is a to-be-processed body, is subjected to cleaning, film formation, or etching (polishing) with use of a liquid or a gas.

In the substrate processing apparatus according to the present embodiment, the mechanism for feeding out the liquid or gas into the process bath TK includes a feed-out mechanism which feeds out the liquid or gas into the process bath TK, and a feed-in mechanism which starts/stops the feed-out of the liquid or gas from the feed-out mechanism.

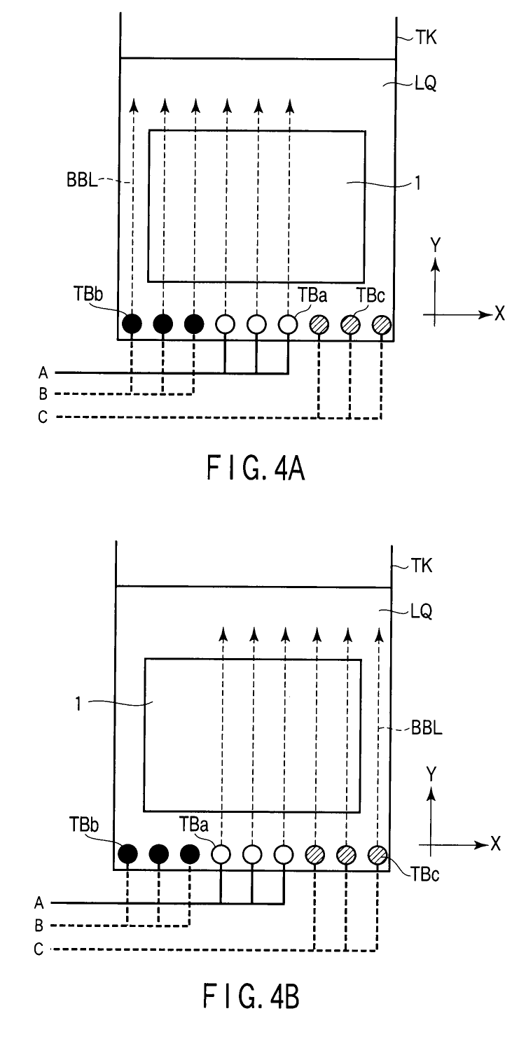

As shown in FIG. 4A and FIG. 4B, the feed-out mechanism is disposed near the bottom part of the process bath TK. In the substrate processing apparatus according to the embodiment, the feed-out mechanism includes a plurality of first tubes TBa, second tubes TBb and third tubes TBc extending in a direction (Z direction) substantially perpendicular to the to-be-processed surfaces of the to-be-processed substrates 1.

The feed-out mechanism further includes an external feed-in mechanism A which feeds the liquid or gas from the outside of the process bath TK into the first tubes TBa, an external feed-in mechanism B which feeds the liquid or gas from the outside of the process bath TK into the second tubes TBb, and an external feed-in mechanism C which feeds the liquid or gas from the outside of the process bath TK into the third tubes TBc.

The axial directions of the first tubes TBa, second tubes TBb and third tubes TBc are substantially parallel to the bottom surface (substantially parallel to the XZ plane), and the first tubes TBa, second tubes TBb and third tubes TBc are juxtaposed in a direction (X direction) substantially perpendicular to the X axis direction such that their axial directions are substantially parallel to each other.

The plural first tubes TBa are disposed at a central portion of the process bath TK in the X direction. The second tubes TBb are disposed at one end portion of the process bath TK in the X direction. The third tubes TBc are disposed at the other end portion of the process bath TK in the X direction.

Each of the first tubes TBa, second tubes TBb and third tubes TBc has a plurality of feed-out ports from which the liquid or gas is fed out. These feed-out ports are disposed, for example, at predetermined intervals in the axial direction (Z direction) of the first tubes TBa, second tubes TBb and third tubes TBc.

In the substrate processing apparatus according to the embodiment, as shown in FIG. 4A and FIG. 4B, air is fed in the first tubes TBa, second tubes TBb and third tubes TBc from the external feed-in mechanism A, external feed-in mechanism B and external feed-in mechanism C, and the air is fed out into the process bath TK from the feed-out ports of the first tubes TBa, second tubes TBb and third tubes TBc. Thereby, the polishing liquid LQ in the process bath TK is stirred.

Specifically, in the substrate processing apparatus according to the embodiment, as shown in FIG. 4A, compressed air is first fed in the first tubes TBa and second tubes TBb which are connected to the external feed-in mechanism A and external feed-in mechanism B, respectively. The compressed air that is fed in the first tubes TBa and second tubes TBb is jetted from the feed-out ports that are formed in the surfaces of the first tubes TBa and second tubes TBb, and rises as bubbles BBL in the polishing liquid LQ. At this time, the range of the region where the bubbles BBL are present in the process bath TK is biased to the left side in the process bath TK in FIG. 4A.

Subsequently, as shown in FIG. 4B, compressed air is fed in the first tubes TBa and third tubes TBc which are connected to the external feed-in mechanism A and external feed-in mechanism C, respectively. The compressed air that is fed in the first tubes TBa and third tubes TBc is jetted from the feed-out ports that are formed in the surfaces of the first tubes TBa and third tubes TBc, and rises as bubbles BBL in the polishing liquid LQ. At this time, the range of the region where the bubbles BBL are present in the process bath TK is biased to the right side in the process bath TK in FIG. 4B.

As has been described above, the distribution of the jetted liquid or air is made spatially or temporally variable. Thereby, the flow of the process liquid LQ in the process bath TK can be varied. Specifically, in the X direction, the first tubes TBa are disposed at a central portion of the process bath TK, the second tubes TBb are disposed at one end portion of the process bath TK, and the third tubes TBc are disposed at the other end portion of the process bath TK. In addition, the first period in which the air is jetted from the first tubes TBa and second tubes TBb and the second period in which the air is jetted from the first tubes TBa and third tubes TBc are alternately repeated. Thereby, the flow of the process liquid LQ in the process bath TK can be varied, and it becomes possible to obtain the same advantageous effect as the effect that is obtained by moving the to-be-processed substrates 1 in the process bath TK.

As has been described above, in the substrate processing apparatus according to the present embodiment, there is no need to move the to-be-processed substrates 1. Thus, without configuring the processing apparatus in a large scale, a greater number of to-be-processed substrates 1 can be processed, and the in-plane uniformity and the uniformity among substrates can be improved by decreasing the difference in progress of the process between, mainly, the central part and end parts of the substrate.

Therefore, the present embodiment can provide a substrate processing apparatus which can reduce a variance in thickness within a substrate surface or between substrates, and can improve product performance and manufacturing yield, like the substrate processing apparatus of the above-described first embodiment.

Next, a substrate processing apparatus and substrate processing method according to a fourth embodiment of the present invention is described with reference to the accompanying drawings. The substrate processing apparatus according to the present embodiment, like the substrate processing apparatus according to the above-described first embodiment, is a substrate processing apparatus which is used when a transparent insulative substrate of a liquid crystal display device, which is a to-be-processed body, is subjected to cleaning, film formation, or etching (polishing) with use of a liquid or a gas.

In the substrate processing apparatus according to the present embodiment, the mechanism for feeding out the liquid or gas into the process bath TK includes a feed-out mechanism which feeds out the liquid or gas into the process bath TK, and a feed-in mechanism which starts/stops the feed-out of the liquid or gas from the feed-out mechanism.

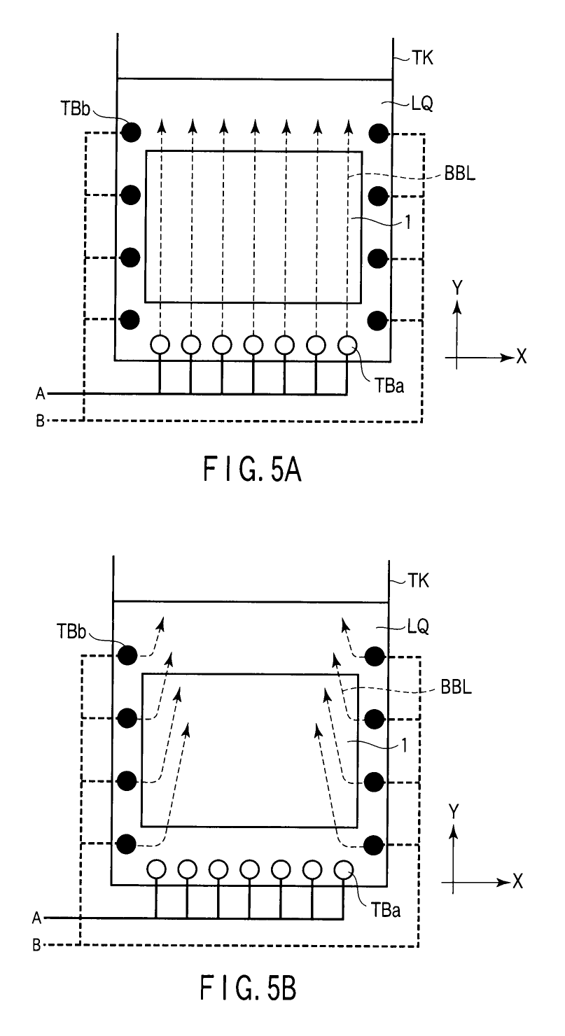

As shown in FIG. 5A and FIG. 5B, the feed-out mechanism is disposed near the bottom part and side surfaces of the process bath TK. In the substrate processing apparatus according to the embodiment, the feed-out mechanism includes a plurality of first tubes TBa and second tubes TBb extending in a direction (Z direction) substantially perpendicular to the to-be-processed surfaces of the to-be-processed substrates 1; an external feed-in mechanism A which feeds the liquid or gas from the outside of the process bath TK into the first tubes TBa; and an external feed-in mechanism B which feeds the liquid or gas from the outside of the process bath TK into the second tubes TBb.

As shown in FIG. 5A and FIG. 5B, the plural first tubes TBa are juxtaposed in the X direction near the bottom part of the process bath TK. Specifically, the axial directions of the first tubes TBa are substantially parallel to the bottom surface (substantially parallel to the XZ plane), and the first tubes TBa are juxtaposed in a direction (X direction) substantially perpendicular to their axial directions such that the axial directions are substantially parallel to each other.

The plural second tubes TBb are juxtaposed in the Y direction near side surfaces of the process bath TK. Specifically, the axial directions of the second tubes TBb are substantially parallel to the side surfaces, and the second tubes TBb are juxtaposed in a direction (Y direction) substantially perpendicular to their axial directions such that the axial directions are substantially parallel to each other. In the substrate processing apparatus according to this embodiment, the plural second tubes TBb are disposed near those side surfaces of the process bath TK, which are substantially perpendicular to the to-be-processed surfaces of the to-be-processed substrates 1.

Each of the first tubes TBa and second tubes TBb has a plurality of feed-out ports from which the liquid or gas is fed out. These feed-out ports are disposed, for example, at predetermined intervals in the axial direction (Z direction) of the first tubes TBa and second tubes TBb.

In the substrate processing apparatus according to the embodiment, as shown in FIG. 5A and FIG. 5B, compressed air is fed in the first tubes TBa and second tubes TBb from the external feed-in mechanism A and external feed-in mechanism B, and the air is fed out into the process bath TK from the feed-out ports of the first tubes TBa and second tubes TBb. Thereby, the polishing liquid LQ in the process bath TK is stirred.

Specifically, in the substrate processing apparatus according to the embodiment, as shown in FIG. 5A, compressed air is first fed in the first tubes TBa which are connected to the external feed-in mechanism A. The compressed air that is fed in the first tubes TBa is jetted from the feed-out ports that are formed in the surfaces of the first tubes TBa, and rises as bubbles BBL in the polishing liquid LQ.

Subsequently, as shown in FIG. 5B, compressed air is fed in the second tubes TBb which are connected to the external feed-in mechanism B. The compressed air that is fed in the second tubes TBb is jetted from the feed-out ports that are formed in the surfaces of the second tubes TBb, and rises as bubbles BBL in the polishing liquid LQ. In the case shown in FIG. 5A, the air is jetted in the Y direction from the vicinity of the bottom surface of the process bath TK. In the case shown in FIG. 5B, the air is jetted in the X direction from the vicinity of the side surfaces of the process bath TK.

As has been described above, the distribution of the jetted liquid or air is made spatially or temporally variable. Thereby, the flow of the process liquid LQ in the process bath TK can be varied. In the X direction, the first tubes TBa are disposed at a central portion of the process bath TK, and the second tubes TBb are disposed at end portions of the process bath TK. In addition, the first period in which the air is jetted from the first tubes TBa and the second period in which the air is jetted from the second tubes TBb are alternately repeated. Thereby, the flow of the process liquid LQ in the process bath TK can be varied, and it becomes possible to obtain the same advantageous effect as the effect that is obtained by moving the to-be-processed substrates 1 in the process bath TK.

As has been described above, in the substrate processing apparatus according to the present embodiment, there is no need to move the to-be-processed substrates 1. Thus, without configuring the processing apparatus in a large scale, a greater number of to-be-processed substrates 1 can be processed, and the in-plane uniformity and the uniformity among substrates can be improved.

Therefore, the present embodiment can provide a substrate processing apparatus and a substrate processing method which can reduce a variance in thickness within a substrate surface or between substrates, and can improve product performance and manufacturing yield, like the substrate processing apparatus of the above-described first embodiment.

The present invention is not limited directly to the above-described embodiments. In practice, the structural elements can be modified and embodied without departing from the spirit of the invention. The above-described embodiments are directed to the examples of substrate processing apparatuses which perform the process with use of a liquid. However, what is used in the process may also be a gas. In this case, an air-tight chamber may be used in place of the process bath.

Besides, what is jetted from the tubes is not limited to the gas, and may be a liquid, or a mixture of a liquid and a gas. The gas that is jetted from the tubes is not necessarily air, and it may be nitrogen gas, for instance. The liquid that is jetted from the tubes may be a cleaning liquid containing a detergent, or an acid or alkaline etchant.

The spatial or temporal distributions of the jetted liquid and air are not limited to those in the above-described embodiments. For example, in the case shown in FIG. 2A and FIG. 2B, one first tube TBa and one second tube TBb are alternately arranged in the X direction. Alternatively, two or more first tubes TBa and two or more second tubes TBb may alternately be disposed in the X direction. Furthermore, for instance, one first tube TBa and a plurality of second tubes TBb may alternately be disposed in the X direction.

For example, in the first embodiment, second embodiment and fourth embodiment, the first period in which the air is jetted from the first tubes TBa and the second period in which the air is jetted from the second tubes TBb are alternately provided. Alternatively, it is possible to partly overlap the first period and second period, thereby providing a period in which air is jetted from both the first tubes TBa and second tubes TBb.

Similarly, as regards the substrate processing apparatus according to the third embodiment, it is possible to provide a period in which air is jetted from all the first tubes TBa, second tubes TBb and third tubes TBc. Besides, it is possible to provide a period in which air is jetted from only the first tubes TBa, only the second tubes TBb or only the third tubes TBc.

In the substrate processing apparatus according to the fourth embodiment, the first tubes TBa and second tubes TBb are disposed such that their axial directions are substantially parallel to each other. Alternatively, the first tubes TBa and second tubes TBb may be disposed such that their axial directions are substantially perpendicular to each other.

Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. A substrate processing apparatus comprising a bath in which a liquid or a gas is fed, and a mechanism which feeds out a liquid or a gas into the bath, and processing a to-be-processed substrate which is disposed in the bath,
the mechanism including first feed-out means and second feed-out means for feeding out the liquid or gas into the bath, first feed-in means for starting/stopping the feed-out of the liquid or gas from the first feed-out means, and second feed-in means for starting/stopping the feed-out of the liquid or gas from the second feed-out means.

2. The substrate processing apparatus according to claim 1, wherein the first feed-out means includes a first tube which is provided with a plurality of feed-out ports from which the liquid or gas is fed out,
the second feed-out means includes a second tube which is provided with a plurality of feed-out ports from which the liquid or gas is fed out, and
the first tube and the second tube are disposed near a bottom part of the bath and are alternately arranged in a direction substantially perpendicular to axial directions of the first tube and the second tube such that the axial directions of the first tube and the second tube are substantially parallel to each other.

3. The substrate processing apparatus according to claim 1, wherein the first feed-out means includes a plurality of first tubes which are provided with first feed-out ports from which the liquid or gas is fed out,
the second feed-out means includes a plurality of second tubes which are provided with second feed-out ports from which the liquid or gas is fed out,
the first tubes and the second tubes are disposed near a bottom part of the bath and are arranged in a direction substantially perpendicular to axial directions of the first tubes and the second tubes such that the axial directions of the first tubes and the second tubes are substantially parallel to each other,
the first tubes are disposed at a central portion of the bath in the direction substantially perpendicular to the axial directions of the first tubes, and
the second tubes are disposed at end portions of the bath in the direction substantially perpendicular to the axial directions of the second tubes.

4. The substrate processing apparatus according to claim 1, wherein the first feed-out means includes a plurality of first tubes which are provided with first feed-out ports from which the liquid or gas is fed out,
the second feed-out means includes a plurality of second tubes which are provided with second feed-out ports from which the liquid or gas is fed out,
the first tubes are disposed near a bottom part of the bath and are arranged in a direction substantially perpendicular to axial directions of the first tubes such that the axial directions of the first tubes are substantially parallel to each other, and
the second tubes are disposed near a side surface of the bath and are arranged in a direction substantially perpendicular to axial directions of the second tubes such that the axial directions of the second tubes are substantially parallel to each other.

5. The substrate processing apparatus according to claim 1, wherein the first feed-in means is configured to cause the first feed-out means to feed out the liquid or gas in a first period, and the second feed-in means is configured to cause the second feed-out means to feed out the liquid or gas in a second period which is different from the first period.

6. The substrate processing apparatus according to claim 1, wherein the mechanism further includes third feed-out means for feeding out a liquid or a gas into the bath, and third feed-in means for starting/stopping the feed-out of the liquid or gas from the third feed-out means,
the first feed-out means includes a first tube which is provided with a plurality of feed-out ports from which the liquid or gas is fed out,
the second feed-out means includes a second tube which is provided with a plurality of feed-out ports from which the liquid or gas is fed out,
the third feed-out means includes a third tube which is provided with a plurality of feed-out ports from which the liquid or gas is fed out,
the first tube, the second tube and the third tube are disposed near a bottom part of the bath and are arranged in a direction substantially perpendicular to axial directions of the first tube, the second tube and the third tube such that the axial directions of the first tube, the second tube and the third tube are substantially parallel to each other,
the first tube is disposed at a central portion of the bath in the direction substantially perpendicular to the axial direction of the first tube,
the second tube is disposed at one end portion of the bath in the direction substantially perpendicular to the axial direction of the second tube, and
the third tube is disposed at the other end portion of the bath in the direction substantially perpendicular to the axial direction of the third tube.

7. The substrate processing apparatus according to claim 6, wherein the first feed-in means is configured to cause the first feed-out means to feed out the liquid or gas in a first period and a second period which is different from the first period, the second feed-in means is configured to cause the second feed-out means to feed out the liquid or gas in the first period, and the third feed-in means is configured to cause the third feed-out means to feed out the liquid or gas in the second period.

8. The substrate processing apparatus according to claim 1, wherein the to-be-processed substrate includes:
a first substrate having a first region which includes a plurality of first electrodes which are arrayed in a matrix; and
a second substrate having a second region which includes a second electrode which is disposed to be opposed to the plurality of first electrodes.

9. A substrate processing method comprising:
disposing a to-be-processed substrate in a bath,
feeding out the liquid or gas into the bath form first feed-out means; and,
feeding out the liquid or gas into the bath from second feed-out means,
wherein a distribution of the jetted liquid or air is made spatially or temporally variable.

10. A substrate processing apparatus comprising a bath in which a liquid or a gas is fed, and a mechanism which feeds out a liquid or a gas into the bath, and processing a to-be-processed substrate which is disposed in the bath,
the mechanism including first feed-out devices and second feed-out devices configured to feed out the liquid or gas into the bath, first feed-in devices configured to start/stop the feed-out of the liquid or gas from the first feed-out devices, and second feed-in devices configured to start/stop the feed-out of the liquid or gas from the second feed-out devices.
